(19) United States
(12) Patent Application Publication
(10) Pub. No.: US 2026/0033088 A1
(43) Pub. Date: Jan. 29, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Yuan YAO, Hefei (CN); Yang SHAO, Kunshan (CN); Yingyu FENG, Kunshan (CN)

(73) Assignees: Hefei Visionox Technology Co., Ltd., Hefei (CN); Visionox Technology Inc., Kunshan (CN)

(21) Appl. No.: 19/271,702

(22) Filed: Jul. 16, 2025

(30) Foreign Application Priority Data
Jul. 24, 2024 (CN) 202411004867.4

(51) Int. Cl. H10H 29/49; H01L 25/16

(52) U.S. Cl. CPC H10H 29/49; H01L 25/167

(57) ABSTRACT

The present disclosure discloses a display panel and a display device. The display panel includes: an active area and a first bezel area arranged in a first direction, the first bezel area being provided with a bonding area; a substrate; a first isolation structure disposed in the active area and on one side of the substrate, the first isolation structure being provided with first isolation openings, and light-emitting elements being provided in the first isolation openings; and a connection portion disposed in the first bezel area, one end of the connection portion being electrically connected to the first isolation structure located in the active area.

### CROSS-REFERENCE TO RELATED APPLICATIONS

This application claims priority to Chinese Patent Application No. 202411004867.4, titled “DISPLAY PANEL AND DISPLAY DEVICE” and filed on Jul. 24, 2024, which is hereby incorporated by reference in its entirety.

### FIELD

The present disclosure relates to the field of displays, and in particular to a display panel and a display device.

### BACKGROUND

With the development of display technologies, the application of display panels is becoming more and more extensive, and correspondingly, requirements for display panels are increasingly high.

However, in the related art, there is a problem of larger bezels of the display panels, limiting further application of the display panels.

### SUMMARY

The present disclosure provides a display panel and a display device to reduce a bezel of the display panel.

According to an aspect of the present disclosure, a display panel is provided. The display panel includes:
an active area and a first bezel area arranged in a first direction, the first bezel area being provided with a bonding area;
a substrate; a first isolation structure disposed in the active area and on one side of the substrate, the first isolation structure being provided with first isolation openings, and light-emitting elements being provided in the first isolation openings; and
a connection portion disposed in the first bezel area, one end of the connection portion being electrically connected to the first isolation structure.

In one embodiment, the other end of the connection portion extends to the bonding area; and the connection portion includes:
a second isolation structure disposed in the first bezel area and on one side of the substrate; and at least one first connection lead, a first end of the first connection lead overlapping and being connected to at least part of the second isolation structure, and a second end of the first connection lead extending to the bonding area.

In one embodiment, the first connection lead extends in the first direction.

In one embodiment, two first connection leads are arranged in a second direction, the first direction intersecting the second direction.

In one embodiment, the second isolation structure and the first isolation structure are disposed in the same layer.

In one embodiment, the second isolation structure is electrically connected to the first isolation structure.

In one embodiment, the second isolation structure is provided with no isolation opening.

In one embodiment, an orthographic projection of the second isolation structure on the substrate covers at least part of an orthographic projection of the first isolation structure on the substrate.

In one embodiment, the orthographic projection of the first isolation structure on the substrate covers at least part of the orthographic projection of the second isolation structure on the substrate; and in the first direction, the orthographic projection of the first isolation structure on the substrate is at least partially misaligned with the orthographic projection of the second isolation structure on the substrate.

In one embodiment, the connection portion further includes at least one second connection lead extending in the second direction, each second connection lead being electrically connected to at least two first connection leads.

In one embodiment, the connection portion further includes at least one third connection lead extending in the first direction, a first end of the third connection lead overlapping and being connected to at least part of the second isolation structure, and a second end of the third connection lead being electrically connected to the second connection lead.

In one embodiment, the first connection lead, the second connection lead and the third connection lead are electrically connected to form a mesh structure.

In one embodiment, the second connection lead is located between the bonding area and the active area, and/or the third connection lead is located between two of the first connection leads, and/or the first connection leads and the third connection lead are uniformly distributed in the second direction.

In one embodiment, at least parts of at least two of the first connection lead, the second connection lead and the third connection lead are disposed in the same layer.

In one embodiment, at least parts of the first connection lead, the second connection lead and the third connection lead are disposed in the same layer.

In one embodiment, the substrate includes a substrate base and a drive circuit layer disposed on the substrate base, the drive circuit layer including a predetermined metal layer close to the first isolation structure, and the first connection lead, the second connection lead, and the third connection lead each including a portion located in the predetermined metal layer, where the portion of the first connection lead that is located in the predetermined metal layer overlaps and is connected to the second isolation structure.

In one embodiment, the drive circuit layer includes an active layer, a first metal layer, a second metal layer, and a third metal layer stacked in sequence on the substrate base, the predetermined metal layer being the third metal layer.

In one embodiment, the drive circuit layer further includes a fourth metal layer, the predetermined metal layer being the fourth metal layer.

In one embodiment, the drive circuit layer further includes a fifth metal layer, the predetermined metal layer being the fifth metal layer.

In one embodiment, the second isolation structure is connected to the first connection lead by means of a via hole.

In one embodiment, each of the first connection leads is connected to the second isolation structure by means of at least two via holes arranged in the first direction.

In one embodiment, in a thickness direction of the display panel, at least one insulating layer is provided between the first connection lead and the second isolation structure, and the via hole is formed in the insulating layer.

In one embodiment, the connection portion further includes a third isolation structure located in the first bezel area; the third isolation structure is provided with a third isolation opening, and a dummy light-emitting element is provided in the third isolation opening; and the third isolation structure is located between the via hole and the active area.

In one embodiment, the third isolation structure and the first isolation structure are disposed in the same layer.

In one embodiment, the third isolation structure is electrically connected to the first isolation structure.

In one embodiment, the third isolation structure, the second isolation structure and the first isolation structure are integrated with one another.

In one embodiment, the third isolation structure and the first isolation structure are mesh connected.

In one embodiment, the display panel further includes at least one second bezel area. The second bezel area and the active area are arranged in a second direction, and/or the second bezel area and the first bezel area are located on opposite sides of the active area in the first direction, the second direction intersecting the first direction; and the second bezel area is provided with no connection portion that electrically connects the first isolation structure to the bonding area.

In one embodiment, in a thickness direction of the display panel, an orthographic projection of the connection portion is located outside an orthographic projection of the second bezel area.

In one embodiment, the display panel further includes a fourth isolation structure located in the second bezel area, where the fourth isolation structure is provided with a fourth isolation opening; and a dummy light-emitting element is provided in the fourth isolation opening.

In one embodiment, the fourth isolation structure and the first isolation structure are disposed in the same layer.

In one embodiment, the fourth isolation structure is electrically connected to the first isolation structure.

In one embodiment, the fourth isolation structure and the first isolation structure are mesh connected.

In one embodiment, the substrate includes a substrate base and a drive circuit layer disposed on the substrate base, a portion of the drive circuit layer that is located in the second bezel area being formed with dummy pixel drive circuits; each of the dummy pixel drive circuits corresponds to at least one dummy light-emitting element; and the dummy pixel drive circuit is insulated from the corresponding dummy light-emitting element.

In one embodiment, the substrate includes a substrate base and a drive circuit layer disposed on the substrate base, a portion of the drive circuit layer that is located in the active area being provided with pixel drive circuits, each of the pixel drive circuits being connected to at least one of the light-emitting elements.

In one embodiment, a portion of the drive circuit layer that is located in the first bezel area is provided with power signal leads, each of the power signal leads having one end electrically connected to the active area and the other end extending to the bonding area.

In one embodiment, the first isolation structure includes a support portion and a crown; and in a thickness direction of the display panel, an orthographic projection of the support portion on the substrate is located within an orthographic projection of the crown on the substrate, where the support portion is an electrically conductive structure.

In one embodiment, the display panel further includes at least one dam surrounding the active area, the dam being provided with a dam opening.

In one embodiment, the display panel further includes first electrodes disposed in the isolation openings and located on a side of the light-emitting elements away from the substrate, where the first electrodes overlap and are connected to the support portion.

According to another aspect of the present disclosure, a display panel is provided.

### The Display Panel Includes:

an active area and a first bezel area arranged in a first direction, the first bezel area being provided with a bonding area;
a substrate;
a first isolation structure disposed in the active area and on one side of the substrate, the first isolation structure being provided with first isolation openings, and light-emitting elements being provided in the first isolation openings; and
a connection portion having one end electrically connected to a portion of the first isolation structure that is located in an active area, where the connection portion is located only in the first bezel area.

In one embodiment, the other end of the connection portion extends to the bonding area; and the connection portion includes:
a second isolation structure disposed in the first bezel area and on one side of the substrate; and
at least one first connection lead, a first end of the first connection lead overlapping and being connected to at least part of the second isolation structure, and a second end of the first connection lead extending to the bonding area.

In one embodiment, the first connection lead extends in the first direction.

In one embodiment, two first connection leads are arranged in a second direction, the first direction intersecting the second direction.

In one embodiment, the second isolation structure and the first isolation structure are disposed in the same layer.

In one embodiment, the second isolation structure is electrically connected to the first isolation structure.

In one embodiment, the second isolation structure is provided with no isolation opening.

In one embodiment, an orthographic projection of the second isolation structure on the substrate covers at least part of an orthographic projection of the first isolation structure on the substrate.

In one embodiment, the orthographic projection of the first isolation structure on the substrate covers at least part of the orthographic projection of the second isolation structure on the substrate; and in the first direction, the orthographic projection of the first isolation structure on the substrate is at least partially misaligned with the orthographic projection of the second isolation structure on the substrate.

In one embodiment, the second isolation structure is connected to the first connection lead by means of a via hole.

In one embodiment, in a thickness direction of the display panel, at least one insulating layer is provided between the first connection lead and the second isolation structure, and the via hole is formed in the insulating layer.

In one embodiment, the connection portion further includes a third isolation structure located in the first bezel area; the third isolation structure is provided with a third isolation opening, and a dummy light-emitting element is provided in the third isolation opening; and the third isolation structure is located between the via hole and the active area.

In one embodiment, the third isolation structure and the first isolation structure are disposed in the same layer.

In one embodiment, the third isolation structure is electrically connected to the first isolation structure.

In one embodiment, the third isolation structure, the second isolation structure and the first isolation structure are integrated with one another.

In one embodiment, the third isolation structure and the first isolation structure are mesh connected.

In one embodiment, the display panel further includes at least one second bezel area. The second bezel area and the active area are arranged in a second direction, and/or the second bezel area and the first bezel area are located on opposite sides of the active area in the first direction, the second direction intersecting the first direction; and the second bezel area is provided with no connection portion that electrically connects the first isolation structure to the bonding area.

In one embodiment, in a thickness direction of the display panel, an orthographic projection of the connection portion is located outside an orthographic projection of the second bezel area.

According to still another aspect of the present disclosure, a display device is provided, including the display panel as described above.

It should be understood that the content described in this section is not intended to identify key or important features of embodiments of the present disclosure, and not intended to limit the scope of the present disclosure. Other features of the present disclosure will be easily understood through the following description.

### BRIEF DESCRIPTION OF THE DRAWINGS

In order to more clearly illustrate the embodiments of the present disclosure, the drawings required for the descriptions of the embodiments will be briefly described below. The drawings in the following description are only some embodiments of the present disclosure.

FIG. 1 is a structural schematic diagram of a display panel according to an embodiment of the present disclosure;

FIG. 2 is a cross-sectional view taken along line A1A2 of FIG. 1;

FIG. 3 is a cross-sectional view taken along line A3A4 of FIG. 1;

FIG. 4 is a partial enlarged view of FIG. 1;

FIG. 5 is another partial enlarged view of FIG. 1;

FIG. 6 is still another partial enlarged view of FIG. 1;

FIG. 7 is yet another partial enlarged view of FIG. 1;

FIG. 8 is a structural schematic circuit diagram of a pixel drive circuit according to an embodiment of the present disclosure; and

FIG. 9 is a structural schematic diagram of a display device according to an embodiment of the present disclosure.

### DETAILED DESCRIPTION OF THE EMBODIMENTS

The embodiments of the present disclosure will be clearly and completely described below with reference to the accompanying drawings for the embodiments of the present disclosure. Apparently, the described embodiments are merely some of, rather than all of, the embodiments of the present disclosure.

It should be noted that the terms such as “first” and “second” in the description and the claims of the present disclosure and in the aforementioned accompanying drawings are used to distinguish similar objects, and do not necessarily describe a specific order of precedence. It should be understood that the data used in this way can be interchanged where appropriate, so that the embodiments of the present disclosure described herein can be implemented in a sequence other than those illustrated or described herein. In addition, the terms “include” and “have” and any variation thereof are intended to cover a non-exclusive inclusion, for example, a process, method, system, product, or apparatus that includes a series of steps or units is not necessarily limited to those steps or units that are explicitly listed, but may include other steps or units not explicitly listed or inherent to such processes, methods, products or apparatuses.

As mentioned above, the display panel in the related art has the problem of having a large bezel, and the inventors have found through extensive research that the reason for this problem is that in the related art, it is necessary for the display panel to provide, at a bezel, a first electrode power line surrounding an active area. The first electrode power line connects a first electrode corresponding to a light-emitting element in the display panel to a drive chip bonded to a bonding area. In other words, it is necessary for each bezel area of the display panel to route the first electrode power line, so that each bezel area of the display panel is relatively large, and the bezel of the display panel is relatively large. The first electrode is, for example, a cathode.

For the problem described above, the present disclosure provides the following solutions.

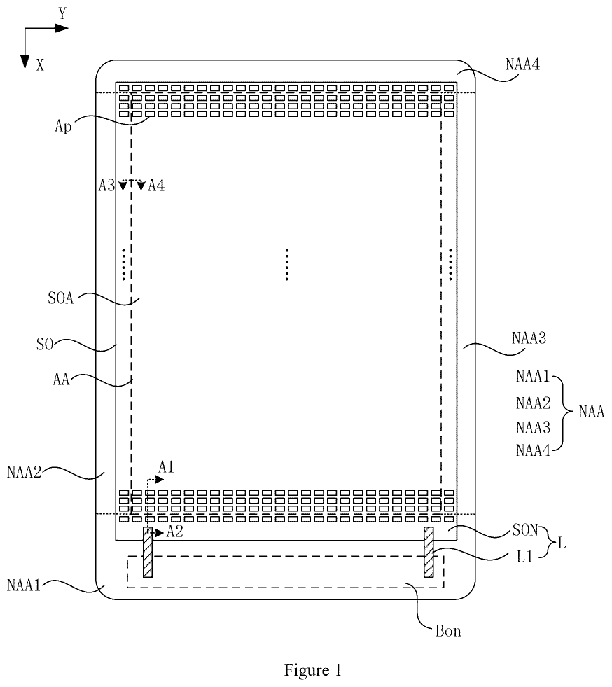

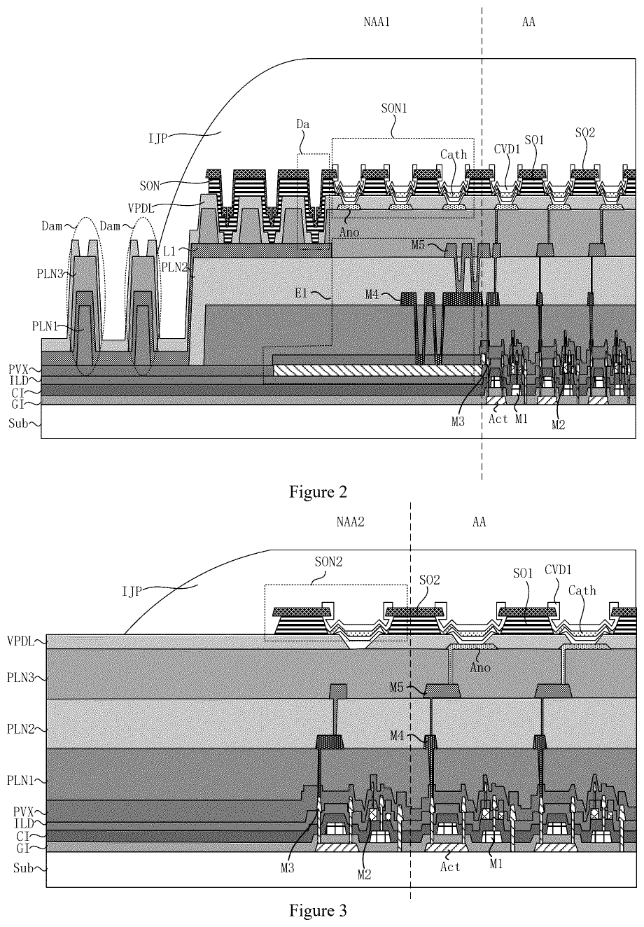

FIG. 1 is a structural schematic diagram of a display panel according to an embodiment of the present disclosure, FIG. 2 is a cross-sectional view taken along line A1A2 of FIG. 1, and FIG. 3 is a cross-sectional view taken along line A3A4 of FIG. 1. Reference is made to FIGS. 1 to 3. The display panel includes: an active area AA and a first bezel area NAA1 arranged in a first direction X, the first bezel area NAA1 having a bonding area Bon disposed therein. The display panel further includes a substrate, a first isolation structure SOA, and a connection portion L. The first isolation structure SOA is disposed in the active area and on one side of the substrate. The first isolation structure SOA is formed with first isolation openings Ap, and light-emitting elements are provided in the first isolation openings Ap. One end of the connection portion L is electrically connected to the first isolation structure SOA.

Specifically, the display panel may be an organic light-emitting diode (OLED) display panel, a micro light-emitting diode (Micro-LED) display panel, etc. The light-emitting elements in the display panel are current-type devices that need to emit light in response to a drive current. A pixel drive circuit is provided in the substrate, and provides a drive current for the light-emitting element. In the related art, a first electrode corresponding to the light-emitting element of the display panel is of an entire-layer structure, and the first electrode is made of a metallic material. In order to ensure the light transmittance of the first electrode, the thickness of the first electrode is relatively small. However, the relatively small thickness will result in a larger resistance of the first electrode. In order to make the difference in voltage received by the first electrode corresponding to each light-emitting element relatively small, a connection portion is provided around the bezel area of the display panel in the related art, the impedance of the connection portion is relatively small, and the difference in voltage received by the first electrode corresponding to each light-emitting element can be reduced. However, this will make each bezel area of the display panel relatively large. The first electrode is, for example, a cathode.

In this embodiment, the display panel includes a first isolation structure SOA, the first isolation structure SOA having electrical conductivity; and the light-emitting element is disposed in the opening formed by the first isolation structure SOA. That is, the first isolation structure SOA does not block the light emitted from the light-emitting element, the thickness of the first isolation structure SOA can thus be set to be relatively large, and the impedance of the first isolation structure SOA is also relatively small. In view of this, in this embodiment a connection portion L is provided in the first bezel area NAA1. The connection portion L may transmit a first electrode voltage transmitted in the bonding area Bon to the first isolation structure SOA in the active area AA, and the first electrode voltage is then transmitted to the first electrode corresponding to each light-emitting element through the first isolation structure SOA in the active area AA. Since the impedance of the first isolation structure SOA is relatively small, the difference in the first electrode voltage received by the first electrode corresponding to each light-emitting element is also relatively small, and the display uniformity of the display panel is relatively good. In addition, in this embodiment, the connection portion L is provided only in the first bezel area NAA1, and only the first bezel area NAA1 has a larger size. That is, the connection portion L is only required to extend in the first direction X in the first bezel area NAA1, without having to be disposed around the active area. Therefore, only the first bezel area NAA1 has a larger size, and the other bezel areas of the display panel can be configured to have a relatively small size or no other bezel areas are provided, so that this embodiment can significantly reduce the bezel of the display panel.

The display panel employed in the embodiment includes an active area and a first bezel area arranged in a first direction, the first bezel area being provided with a bonding area. The display panel further includes: a substrate; and a first isolation structure disposed in the active area and on one side of the substrate. The first isolation structure is formed with first isolation openings, and light-emitting elements are provided in the first isolation openings. The display panel further includes a connection portion disposed in the first bezel area. The connection portion has one end electrically connected to the first isolation structure and the other end extending to the bonding area. The display panel is provided with a first isolation structure with a smaller impedance. The provision of the connection portion only in the first bezel area can ensure that the difference in the voltage received by the first electrode of each light-emitting element in the display panel is relatively small, and it is not necessary to provide connection portions in the other bezel areas, so that the size of the other bezel areas can be reduced.

In one embodiment, the display panel includes an isolation structure SO. The isolation structure SO is disposed on one side of the substrate, and the first isolation structure SOA is a portion of the isolation structure SO that is located in the active area.

The composition, preparation and other details of the isolation structure SO are further described in PCT/CN 2023/134518, 202310759370.2, 202310740412.8, 202310707209.0, 202311346196.5, and 202310692671.8, which are incorporated herein by reference.

In one embodiment, referring to FIGS. 1 to 3, the isolation structure SO includes a support portion SO1 and a crown SO2. In a thickness direction of the display panel, an orthographic projection of the support portion SO1 on the substrate is located within an orthographic projection of the crown SO2 on the substrate. The support portion SO1 is an electrically conductive structure, and the crown SO2 is also an electrically conductive structure. Compared to the first electrode corresponding to the light-emitting element, the support portion SO1 has a thicker thickness and a smaller impedance.

In one embodiment, the display panel includes an active area AA and a bezel area NAA that at least partially surrounds the active area AA. In this embodiment, by taking an example in which the bezel area NAA completely surrounds the active area AA, the bezel area NAA includes a first bezel area NAA1 and at least one second bezel area. The second bezel area and the active area AA are arranged in a second direction Y, and/or the second bezel area and the first bezel area are located on two sides of the active area AA in the first direction X. The at least one second bezel area may include a first second bezel area NAA2, a second bezel area NAA3, and a third second bezel area NAA4. The first second bezel area NAA2 and the second bezel area NAA3 are located on two sides of the active area AA in the second direction Y, and the third second bezel area NAA4 and the first bezel area NAA1 are located on opposite sides of the active area AA in the first direction X. The first direction X intersects the second direction Y. In one embodiment, the first direction X may be a column direction, and the second direction Y may be a row direction. The second bezel area is provided with no connection portion for connecting the first isolation structure SOA to the bonding area Bon. In other words, in the thickness direction of the display panel, an orthographic projection of the connection portion is located outside an orthographic projection of the second bezel area. That is, the connection portion L for connecting the first isolation structure SOA to the bonding area Bon is provided only in the first bezel area NAA1, so that the second bezel area can be provided with fewer traces, and the size of the second bezel area can be reduced.

In one embodiment, the bonding area Bon is configured to bond the drive chip. After the drive chip is bonded to the display panel, the drive chip is electrically connected to the connection portion L to provide the connection portion L with a first electrode voltage required for the light-emitting element. The drive chip may be a chip on film (COF) or a chip on glass (COG), etc., which is not specifically limited in this embodiment.

In one embodiment, with continued reference to FIGS. 1 and 2, the other end of the connection portion L extends to the bonding area Bon, and specifically may be electrically connected to a pad in the bonding area Bon. The connection portion L includes: a second isolation structure SON, where the second isolation structure SON can also be understood to be a portion of the isolation structure SO that is located in the first bezel area NAA1; and at least one first connection lead L1, a first end of the first connection lead L1 overlapping and being connected to at least part of the second isolation structure SON, and a second end of the first connection lead L1 being electrically connected to the bonding area Bon.

Specifically, the isolation structure SO in this embodiment is located not only in the active area AA, but also in part of the first bezel area NAA1. That is, the isolation structure SO extends from the active area AA into the first bezel area NAA1. The first connection lead L1 and the isolation structure SO are located in different layers, so that the first connection lead L1 and the isolation structure SO are electrically connected to each other in the thickness direction of the display panel, thereby facilitating manufacturing and ensuring the stability of the electrical connection. Stabilization of signal transmission between the connection lead L1 and the portion of the isolation structure SO that is located in the active area AA (i.e., the first isolation structure SOA) is ensured. It should be noted that the connection lead L1 is not limited to being located in only one layer. The connection lead L1 may extend to the bonding area Bon in one layer and be electrically connected to the bonding pad, or may be rerouted in multiple layers to extend to the bonding area Bon and be electrically connect to the bonding pad.

In one embodiment, the second isolation structure and the first isolation structure are in the same layer.

In one embodiment, the second isolation structure is electrically connected to the first isolation structure, for example, by direct electrical connection or by electrical connection through a third isolation structure SON1 (a third isolation opening being provided on the third isolation structure SON1, which will be described later).

In one embodiment, the second isolation structure is provided with no isolation opening.

In one embodiment, in some other embodiments, the isolation structure SO may not overlap the first bezel area NAA1, that is, the first bezel area is provided with no isolation structure. The connection portion L includes at least one first connection lead L1. One end of the first connection lead L1 extends into the active area AA, and overlaps and is connected to the first isolation structure SOA by means of a via hole. The other end of the connection lead L1 is electrically connected to the bonding area Bon. In this embodiment, the isolation structure SO is misaligned with the first bezel area NAA1, so that the size of the first bezel area NAA1 can be further reduced.

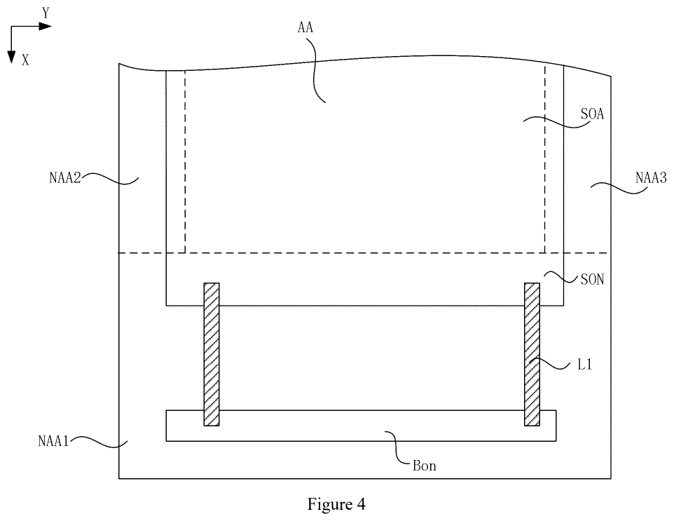

In one embodiment, FIG. 4 is a partial enlarged view of FIG. 1, and reference is made to FIG. 4. In this embodiment, in the first direction X, an orthographic projection of the second isolation structure SON on the substrate covers at least part of an orthographic projection of the first isolation structure SOA on the substrate (i.e., at least part of the isolation structure that is located in the active area AA). The overall shape of the isolation structure SO is the same as the shape of the active area AA, but the area of the isolation structure is larger than the area of the active area. With such an arrangement, in the second direction Y, different first connection leads L1 are electrically connected to each other by means of a portion of the second isolation structure SON that is located between the first connection leads L1, and the overall structure composed of the different first connection leads L1 and the isolation structure between them has a lower impedance, to facilitate a reduction in the difference in voltages of the first electrodes corresponding to the light-emitting elements in different columns of the display panel, so that the problem of display unevenness can be alleviated.

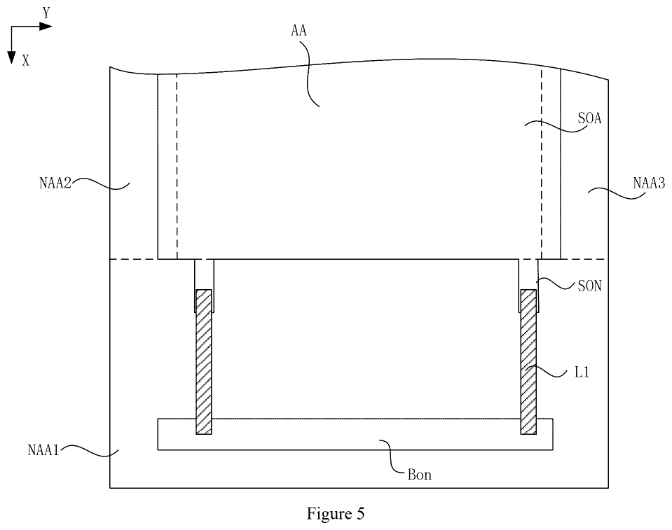

In one embodiment, FIG. 5 is another partial enlarged view of FIG. 1, and reference is made to FIG. 5. In this embodiment, in the first direction, the orthographic projection of the first isolation structure SOA on the substrate covers at least part of the orthographic projection of the second isolation structure SON on the substrate; and in the first direction X, the orthographic projection of the first isolation structure SOA on the substrate at least partially does not overlap the orthographic projection of the second isolation structure SON on the substrate. In other words, in this embodiment, the second isolation structure SON is a protrusion corresponding to the first connection lead L1 with respect to the active area AA. In this embodiment, it is possible to ensure that the first isolation structure SOA is electrically connected to the first connection lead L1, and also to reduce the isolation structure in the first bezel area NAA1, thereby saving costs.

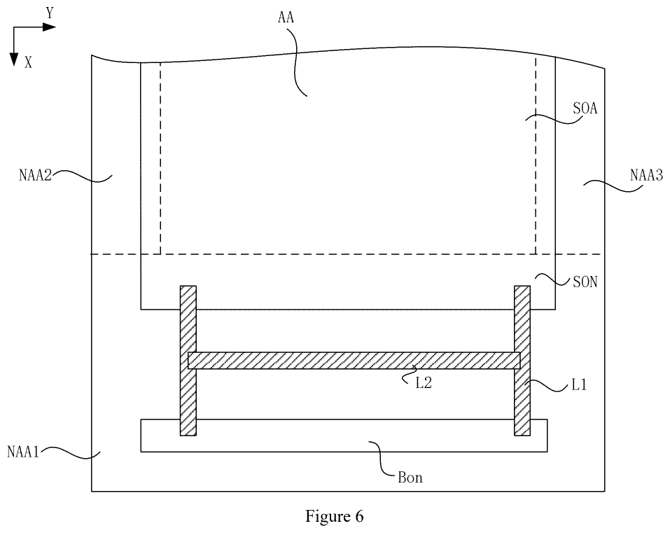

In one embodiment, FIG. 6 is still another partial enlarged view of FIG. 1, and reference is made to FIG. 6. The connection portion L includes at least two first connection leads L1 arranged in the second direction Y. The connection portion further includes at least one second connection lead L2 extending in the second direction Y, each second connection lead L2 being connected to at least two first connection leads L1.

Specifically, in this embodiment, the second connection lead L2 may electrically connect the corresponding first connection leads L1 in the second direction Y. In this way, the impedance of the overall structure composed of the first connection leads L1 and the second connection lead L2 can be reduced, the difference in voltage of the first electrodes corresponding to the light-emitting elements in different columns of the display panel can be further reduced, and the problem of display unevenness can thus be alleviated.

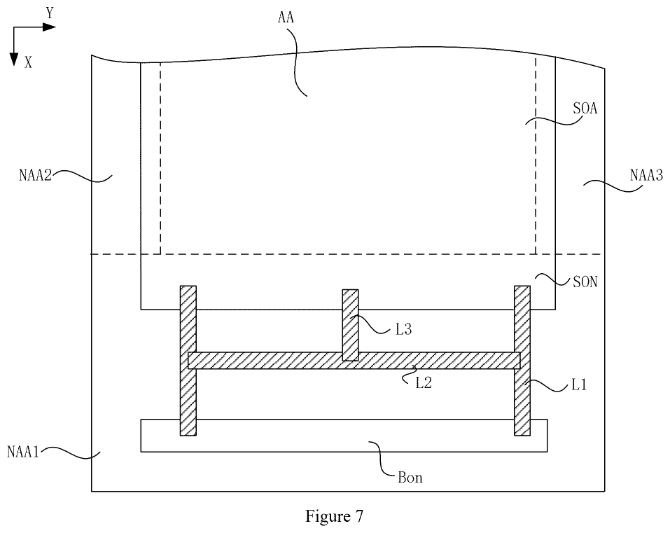

In one embodiment, FIG. 7 is yet another partial enlarged view of FIG. 1, and reference is made to FIG. 7. The connection portion L further includes at least one third connection lead L3 extending in the first direction X. A first end of the third connection lead L3 overlaps and is connected to at least part of the second isolation structure SON, and a second end of the third connection lead L3 is electrically connected to the second connection lead L2. In one embodiment, the first connection lead L1, the second connection lead L2 and the third connection lead L3 are connected to form a mesh structure.

Specifically, in this embodiment, the third connection lead L3, the second connection lead L2 and the first connection lead L1 perpendicularly cross to form a mesh structure. The mesh structure has a lower impedance, so that the difference in voltage of the first electrodes corresponding to the light-emitting elements in different columns of the display panel can be further reduced, and the problem of display unevenness can thus be alleviated.

In one embodiment, with continued reference to FIG. 7, the second connection lead L2 is located between the bonding area Bon and the active area AA.

Specifically, in this embodiment, the first connection lead L1 extends into the bonding area Bon, but not beyond the bonding area Bon. The routing of the second connection lead L2 in the area between the bonding area Bon and the active area AA can connect the first connection leads L1 without increasing the size of the first bezel area NAA1.

In one embodiment, with continued reference to FIG. 7, the third connection lead L3 is located between two first connection leads L1. Specifically, the two first connection leads L1 are located at edges of the first bezel area NAA1 in the second direction Y, respectively, for receiving a first electrode voltage signal transmitted by the bonding area. The third connection lead L3 does not extend to the bonding area Bon, and the third connection lead L3 may overlap and be connected to the portion of the isolation structure that is located in the first bezel area NAA1 (i.e. the second isolation structure SON), so that the third connection lead L3 can also transmit a signal directly to the isolation structure. In the portion of the isolation structure that is located in the active area (i.e., the first isolation structure SOA), both an edge area and a middle area can receive the voltage signal from the connection portion, so that the difference in voltage between the areas is further reduced.

In one embodiment, with continued reference to FIG. 7, the first connection leads L1 and the third connection lead L3 are uniformly distributed in the second direction Y. With such an arrangement, the connection portion can transmit the voltage signal into the first isolation structure SOA more uniformly, so that the difference in voltage of the voltage signal received by each portion of the first isolation structure SOA is smaller, thereby further alleviating the problem of display unevenness.

In one embodiment, in the above implementation, at least parts of at least two of the first connection lead L1, the second connection lead L2 and the third connection lead L3 are disposed in the same layer. For example, both the second connection lead L2 and the third connection lead L3 are arranged in the same layer as a portion of the first connection lead L1 that directly overlaps and is connected to the second isolation structure SON. The arrangement of this embodiment makes it easier to make the electrical connection between the first connection lead L1, the second connection lead L2 and the third connection lead L3, thereby reducing the manufacturing difficulty of the display panel and reducing the manufacturing cost of the display panel.

In one embodiment, referring to FIGS. 2 and 3, the substrate includes a substrate base Sub and a drive circuit layer disposed on the substrate base Sub. The drive circuit layer includes a predetermined metal layer close to the first isolation structure SOA, and the first connection lead L1, the second connection lead L2, and the third connection lead L3 each include a portion located in the predetermined metal layer. The portion of the first connection lead L1 that is located in the predetermined metal layer overlaps and is connected to the second isolation structure SON.

Specifically, the substrate base Sub may be a rigid substrate base made of, for example, glass, sapphire, diamond or silicon. The substrate base Sub may alternatively be a flexible substrate base made of, for example, polyimide. A plurality of pixel drive circuits are formed in the drive circuit layer, each pixel drive circuit being configured to drive at least one light-emitting element. A buffer layer may be further provided between the substrate base Sub and the drive circuit layer. The drive circuit layer includes metal layers, and the predetermined metal layer is the metal layer of the plurality of metal layers closest to the isolation structure. The portion of the first connection lead for overlapping and being connected to the second isolation structure is disposed in the predetermined metal layer, and the via hole between this portion and the second isolation structure has a relatively small depth to facilitate manufacturing. Moreover, the second connection lead L2 and the third connection lead L3 may be further disposed in the predetermined metal layer. The predetermined metal layer has more idle areas, while the other metal layers may be provided with fan-out lines of data lines or other traces, so that the arrangement of this embodiment does not occupy the space of the other metal layers, thereby avoiding occupying the area of the other metal layers where the fan-out lines of the data lines are provided.

In one embodiment, the drive circuit layer includes an active layer Act, a first metal layer M1, a second metal layer M2, and a third metal layer M3 stacked in sequence on the substrate base Sub, the predetermined metal layer being the third metal layer M3. In one embodiment, the drive circuit layer further includes a fourth metal layer M4 disposed on a side of the third metal layer M3 away from the second metal layer M2, the predetermined metal layer being the fourth metal layer. In one embodiment, the drive circuit layer further includes a fifth metal layer M5 disposed on a side of the fourth metal layer M4 away from the third metal layer M3, the predetermined metal layer being the fifth metal layer M5.

Specifically, the pixel drive circuit includes at least two transistors and at least one capacitor. The active layer Act of the drive circuit layer is configured to form active structures of the transistors, the first metal layer M1 is configured to form gates of the transistors and a first plate of the capacitor, the second metal layer M2 is configured to form a second plate of the capacitor, the third metal layer M3 is configured to form sources and drains of the transistors, the fourth metal layer M4 serves as an interconnection layer which may provide interconnection between the pixel drive circuit and a second electrode corresponding to the light-emitting element and may be configured to form a power supply line or the like corresponding to the pixel drive circuit, and the fifth metal layer M5 may be configured to form a data line or the like. Of course, when there is a different number of metal layers of the drive circuit layer, the predetermined metal layer may also not be the fifth metal layer. The drive circuit layer further includes a gate insulating layer GI located between the active layer Act and the first metal layer M1, an interlayer insulating layer CI located between the first metal layer M1 and the second metal layer M2, an interlayer dielectric layer ILD located between the second metal layer M2 and the third metal layer M3, an inorganic layer PVX and a first planarization layer PLN1 located between the third metal layer M3 and the fourth metal layer M4, a second planarization layer PLN2 located between the fourth metal layer M4 and the fifth metal layer M5, and a third planarization layer PLN3 covering the fifth metal layer M5. The second electrode is, for example, an anode.

In one embodiment, the display panel further includes a pixel definition layer VPDL. The pixel definition layer VPDL is located between the drive circuit layer and the isolation structure SO, and the pixel definition layer VPDL is formed with pixel openings. The pixel openings correspond to the first isolation openings on a one-to-one basis, and an orthographic projection of the first isolation opening on the substrate base Sub is located within an orthographic projection of the corresponding pixel opening on the substrate base Sub in the thickness direction of the display panel. The pixel opening partially exposes the second electrode Ano corresponding to the light-emitting element. The first electrode Cath corresponding to the light-emitting element is at least partially disposed in the first isolation opening, and overlaps and is connected to the first isolation structure. The light-emitting element may include a hole injection layer, a hole transport layer, an electron blocking layer, a light-emitting layer, a hole blocking layer, an electron transport layer and an electron injection layer which are located between the second electrode Ano and the first electrode Cath. The light-emitting element of the display panel may include a first color light-emitting element, a second color light-emitting element, and a third color light-emitting element. The light-emitting colors of the first color light-emitting element, the second color light-emitting element and the third color light-emitting element are all different. For example, the light emitted from the first color light-emitting element is red, the light emitted from the second color light-emitting element is green, and the light emitted from the third color light-emitting element is blue. Each light-emitting element is further provided with a corresponding first inorganic encapsulation layer CVD1. The display panel further includes an organic encapsulation layer IJP located on a side of the first inorganic encapsulation layer CVD1 away from the substrate base and covering the entire active area AA and part of the bezel area NAA. The display panel may further include a second inorganic encapsulation layer covering the organic encapsulation layer IJP.

In one embodiment, with continued reference to FIG. 2, the second isolation structure SON is connected to the first connection lead L1 by means of a via hole Da.

Specifically, in this embodiment, an insulating layer may be formed after the corresponding portion of the first connection lead L1 is formed in the fifth metal layer M5, and the second isolation structure is then formed on the insulating layer. Forming the insulating layer includes forming a third planarization layer PLN3, and etching an opening in a portion of the third planarization layer PLN3 that covers the first connection lead L3; and providing a pixel definition layer VPDL along a via hole, exposing the first connection lead L1, and subsequently extending the second isolation structure along the via hole formed by the pixel definition layer to form the via hole Da. That is, the via hole in this embodiment is formed in the insulating layer, and the insulating layer includes the third planarization layer PLN3 and the pixel definition layer VPDL. In some embodiments, each first connection lead L1 is connected to the second isolation structure by means of only one via hole Da, and the size of the overlapping portion of the first connection lead L1 and the second isolation structure is relatively small, so that the size of the first bezel area NAA1 can be reduced. In some other embodiments, each first connection lead L1 is connected to the second isolation structure by means of at least two via holes Da arranged in the first direction X. As shown in FIG. 2, each first connection lead L1 overlaps and is connected to three via holes Da arranged in the first direction X. In this way, the contact resistance between the first connection lead L1 and the isolation structure can be reduced, thereby reducing the signal transmission loss, and facilitating a reduction in the power consumption of the display panel.

In one embodiment, with continued reference to FIG. 2, the connection portion further includes a third isolation structure SON1. The third isolation structure SON1 is located in the first bezel area NAA1, and the third isolation structure SON1 is provided with a third isolation opening. A dummy light-emitting element is provided in the third isolation opening. The third isolation structure SON1 is located between the via hole Da and the active area AA.

Specifically, the third isolation structure SON1 can also be understood as part of the isolation structure SO, i.e. the portion of the isolation structure that is located in the first bezel area NAA1 includes the third isolation structure SON1 and the second isolation structure SON, and the second isolation structure SON is connected to the first connection lead L1 by means of the via hole Da. The third isolation structure SON1 is continuous with the first isolation structure SON, so that the light-emitting element at the edge in the active area AA is not the outermost light-emitting element during evaporation. That is, each light-emitting element in the active area AA is not the outermost light-emitting element, so that the uniformity of evaporation of the light-emitting elements in the active area AA can be improved, and defects in evaporation of the light-emitting element at the edge in the active area can be avoided. It can be understood that the dummy light-emitting element is not connected to the pixel drive circuit, that is, is not used for light emission. In addition, at least one dummy pixel is provided in the first bezel area NAA1 and corresponding to each column of pixels of the active area AA. Each pixel includes at least one first color light-emitting element, at least one second color light-emitting element and at least one third color light-emitting element. Each dummy pixel includes at least one first color dummy light-emitting element, at least one second color dummy light-emitting element, and at least one third color dummy light-emitting element.

In one embodiment, the third isolation structure and the first isolation structure are disposed in the same layer. In one embodiment, the third isolation structure is electrically connected to the first isolation structure. In one embodiment, the third isolation structure, the second isolation structure and the first isolation structure are unitary structures integrated with one another. Further, the third isolation structure and the first isolation structure are mesh connected.

In one embodiment, with continued reference to FIG. 3, the display panel further includes a fourth isolation structure SON2 located in the second bezel area. The fourth isolation structure SON2 is formed with a fourth isolation opening. A dummy light-emitting element is provided in the fourth isolation opening. The fourth isolation structure SON2 can be understood as a portion of the isolation structure SO that is located in the second bezel area.

Specifically, the purpose of providing a dummy light-emitting element in the fourth isolation opening is the same as the purpose of providing a dummy light-emitting element in the third isolation opening, that is, to improve the uniformity of evaporation of the light-emitting elements in the active area AA. In this embodiment, such an arrangement makes the evaporation of each light-emitting element in the active area AA more uniform, and improves the display uniformity. It should be noted that in this embodiment, although only the cross-sectional view of the first second bezel area NAA2 is illustrated, the cross-sectional views of the second bezel area NAA3 and the third second bezel area NAA3 are the same as the cross-sectional view of the first second bezel area NAA2, and will not be illustrated again here. In addition, although only one dummy light-emitting element is illustrated in FIG. 3, it is not limited thereto. For the first second bezel area, each row may include at least one dummy pixel, the dummy pixel including at least one first color dummy light-emitting element, at least one second color dummy light-emitting element, and at least one third color dummy light-emitting element.

In one embodiment, the fourth isolation structure and the first isolation structure are disposed in the same layer. In one embodiment, the fourth isolation structure is electrically connected to the first isolation structure. In one embodiment, the fourth isolation structure and the first isolation structure are mesh connected.

In one embodiment, referring to FIG. 2, the display panel further includes at least one dam Dam surrounding the active area. The dam Dam is provided with a dam opening. The dam Dam may include the first planarization layer PLN1, the fifth metal layer M5, the third planarization layer PLN3 and the pixel definition layer VPDL. The dam opening is formed by the pixel definition layer VPDL. The dam Dam is configured to prevent overflow of the organic encapsulation layer IJP. The dam opening is configured for gas transmission, and gas released from the organic layer (the third planarization layer PLN3) can be released to the outside.

In one embodiment, referring to FIG. 2, a portion of the drive circuit layer that is located in the first bezel area NAA1 is provided with power signal leads E1. One end of the power signal lead E1 is electrically connected to the active area AA, and the other end of the power signal lead E1 is electrically connected to the bonding area Bon. The power signal lead E1 is configured to transmit a first power signal ELVDD in the bonding area E1 to a first power signal line in the active area. The power signal lead E1 may be rerouted from the fifth metal layer M5 to the fourth metal layer M4 and then from the fourth metal layer M4 to the third metal layer M3.

In one embodiment, the portion of the drive circuit layer that is located in the first bezel area NAA1 further includes fan-out lines (not shown). One end of the fan-out line is electrically connected to the active area, and in particular to the data line in the active area, and the other end of the fan-out line is electrically connected to the bonding area. The fan-out line is configured to provide a data signal to the data line. The fan-out line may be disposed at the second metal layer M2 and/or the first metal layer M1.

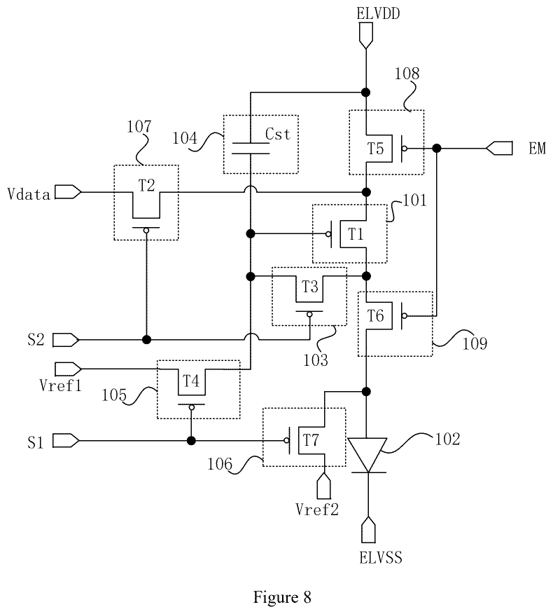

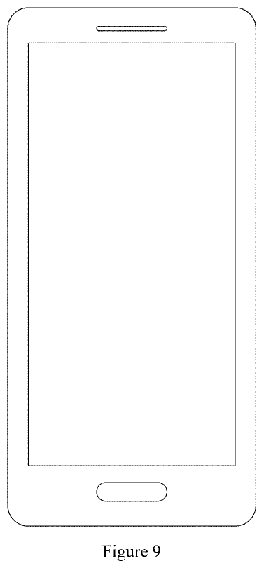

In one embodiment, FIG. 8 is a structural schematic circuit diagram of a pixel drive circuit according to an embodiment of the present disclosure. Referring to FIG. 8, the pixel drive circuit includes a drive module 101, a data writing module 107 and a storage module 104. The data writing module 107 is configured to write a data voltage Vdata into the drive module 101. The drive module 101 is configured to generate a drive current according to the data voltage Vdata, and the light-emitting element 102 emits light in response to the drive current. The storage module 104 is configured to maintain a potential at a control terminal of the drive module 101.

Specifically, the specific operation process of the pixel drive circuit may include a charging phase and a light-emitting phase. During the charging phase, the data writing module 107 writes the data voltage Vdata into the control terminal of the drive module 101. During the light-emitting phase, the storage module 104 maintains the potential at the control terminal of the drive module 101, and the drive module 101 generates a corresponding drive current based on the data voltage Vdata, so that the corresponding light-emitting element emits light.

In one embodiment, with continued reference to FIG. 8, the pixel drive circuit further includes: a threshold compensation module 103, a first initialization module 105, a second initialization module 106, a first light emission control module 108 and a second light emission control module 109. A first terminal of the data writing module 107 receives the data voltage Vdata, a second terminal of the data writing module 107 is electrically connected to a first terminal of the drive module 101, and a control terminal of the data writing module 107 receives a second scan signal S2. A first terminal of the threshold compensation module 103 is electrically connected to a second terminal of the drive module 101, a second terminal of the threshold compensation module 103 is electrically connected to the control terminal of the drive module 101, and a control terminal of the threshold compensation module 103 receives the second scan signal S2. A first terminal of the first initialization module 105 receives a first initialization signal Vref1, a second terminal of the first initialization module 105 is electrically connected to the control terminal of the drive module 101, and a control terminal of the first initialization module 105 receives a first scan signal S1. A first terminal of the second initialization module 106 receives a second initialization signal Vref2, a second terminal of the second initialization module 106 is electrically connected to the second electrode corresponding to the light-emitting element 102, and a control terminal of the second initialization module receives the first scan signal S1. A first terminal of the first light emission control module 108 receives the first power signal ELVDD, a second terminal of the first light emission control module 108 is electrically connected to the first terminal of the drive module 101, and a control terminal of the first light emission control module 108 is receives a light emission control signal EM. A first terminal of the second light emission control module 109 is electrically connected to the second terminal of the drive module 101, a second terminal of the second light emission control module 109 is electrically connected to the second electrode corresponding to the light-emitting element 102, and a control terminal of the second light emission control module 109 receives the light emission control signal EM. A first terminal of the storage module 104 receives the first power signal ELVDD, and a second terminal of the storage module 104 is electrically connected to the control terminal of the drive module 101. The second electrode corresponding to the light-emitting element receives a second power signal ELVSS, where the second power signal ELVSS is the power signal transmitted to the first electrode by the isolation structure and the connection portion described herein.

The operation process of the pixel drive circuit includes an initialization phase, a charging phase and a light-emitting phase.

During the initialization phase, the first scan signal S1 controls the activation of the first initialization module 105 and the second initialization module 106. The control terminal of the drive module 101 is reset by the first initialization signal Vref1 to facilitate the activation during the charging phase. The second initialization signal Vref2 is written into the second electrode corresponding to the light-emitting element 102, preventing the last frame signal from remaining to cause a shadow.

During the charging phase, the second scan signal S2 controls the activation of the data writing module 107 and the threshold compensation module 103. The data voltage Vdata is written into the control terminal of the drive module 101 via the data writing module 107, the drive module 101 and the threshold compensation module 103, and when the difference in voltage between the control terminal of the drive module 101 and the first terminal thereof is equal to a threshold voltage of the drive module 101, the drive module 101 is deactivated, so that the voltage at the control terminal of the drive module 101 includes threshold voltage information of the drive module 101. That is, compensation for the threshold voltage of the drive module 101 is completed during the charging phase.

During the light-emitting phase, the light emission control signal EM controls the activation of the first light emission control module 108 and the second light emission control module 109. The drive module 101 generates a drive current, the storage module 104 maintains the potential at the control terminal of the drive module 101, and the light-emitting element 102 emits light in response to the drive current.

By way of example, the drive module 101 includes a first transistor T1. A first terminal of the first transistor T1 serves as the first terminal of the drive module 101, a second terminal of the first transistor T1 serves as the second terminal of the drive module 101, and a control terminal of the first transistor T1 serves as the control terminal of the drive module 101.

The data writing module 107 includes a second transistor T2. A first terminal of the second transistor T2 serves as the first terminal of the data writing module 107, a second terminal of the second transistor T2 serves as the second terminal of the data writing module 107, and a control terminal of the second transistor T2 serves as the control terminal of the data writing module 107.

The threshold compensation module 103 includes a third transistor T3. A first terminal of the third transistor T3 serves as the first terminal of the threshold compensation module 103, a second terminal of the third transistor T3 serves as the second terminal of the threshold compensation module 103, and a control terminal of the third transistor T3 serves as the control terminal of the threshold compensation module 103.

The first initialization module 105 includes a fourth transistor T4. A first terminal of the fourth transistor T4 serves as the first terminal of the first initialization module 105, a second terminal of the fourth transistor T4 serves as the second terminal of the first initialization module 105, and a control terminal of the fourth transistor T4 serves as the control terminal of the first initialization module 105.

The first light emission control module 108 includes a fifth transistor T5. A first terminal of the fifth transistor T5 serves as the first terminal of the first light emission control module 108, a second terminal of the fifth transistor T5 serves as the second terminal of the first light emission control module 108, and a control terminal of the fifth transistor T5 serves as the control terminal of the first light emission control module 108.

The second light emission control module 109 includes a sixth transistor T6. A first terminal of the sixth transistor T6 serves as the first terminal of the second light emission control module 109, a second terminal of the sixth transistor T6 serves as the second terminal of the second light emission control module 109, and a control terminal of the sixth transistor T6 serves as the control terminal of the second light emission control module 109.

The second initialization module 106 includes a seventh transistor T7. A first terminal of the seventh transistor T7 serves as the first terminal of the second initialization module 106, a second terminal of the seventh transistor T7 serves as the second terminal of the second initialization module 106, and a control terminal of the seventh transistor T7 serves as the control terminal of the second initialization module 106.

The storage module 104 includes a storage capacitor Cst. A first plate of the storage capacitor Cst serves as the second terminal of the storage module 104, and a second plate of the storage capacitor Cst serves as the second terminal of the storage module 104.

It should be noted that the pixel drive circuit may alternatively be of other structures. For example, the pixel drive circuit may be a pixel drive circuit including an oxide thin film transistor.

An embodiment of the present disclosure further provides a display panel, including: an active area and a first bezel area arranged in a first direction, the first bezel area being provided with a bonding area; a substrate; a first isolation structure disposed in the active area and on one side of the substrate, the first isolation structure being provided with first isolation openings, and light-emitting elements being provided in the first isolation openings; and a connection portion having one end electrically connected to the first isolation structure, where the connection portion is located only in the first bezel area.

The connection portion in this embodiment is provided only in the first bezel area. The connection portion may transmit a first electrode voltage transmitted in the bonding area to the first isolation structure in the active area, and the first electrode voltage is then transmitted to the first electrode corresponding to each light-emitting element through the first isolation structure in the active area. Since the impedance of the first isolation structure is relatively small, the difference in the first electrode voltage received by the first electrode corresponding to each light-emitting element is also relatively small, and the display uniformity of the display panel is relatively good. In addition, in this embodiment, the connection portion is provided only in the first bezel area, and only the first bezel area has a larger size. That is, the connection portion is only required to extend in the first direction in the first bezel area, without having to be disposed around the active area. Therefore, only the first bezel area has a larger size, and the other bezel areas of the display panel can be configured to have a relatively small size or no other bezel areas are provided, so that this embodiment can significantly reduce the bezel of the display panel. In one embodiment, when the display panel further includes at least one second bezel area, the second bezel area is adjacent to the first bezel area, and/or the second bezel area is opposite the first bezel area; and the second bezel area is provided with no connection portion for electrically connecting the isolation structure in the active area to the bonding area.

In one embodiment, the other end of the connection portion extends to the bonding area. The connection portion includes: a second isolation structure, where the second isolation structure can also be understood to be a portion of the isolation structure that is located in the first bezel area; and at least one first connection lead, a first end of the first connection lead overlapping and being connected to at least part of the second isolation structure, and a second end of the first connection lead extending to the bonding area.

Specifically, the isolation structure in this embodiment is located not only in the active area, but also in part of the first bezel area. That is, the isolation structure extends from the active area into the first bezel area. The first connection lead and the isolation structure are located in different layers, so that the first connection lead and the isolation structure are electrically connected to each other in the thickness direction of the display panel, thereby facilitating manufacturing and ensuring the stability of the electrical connection. Stabilization of signal transmission between the connection lead and the portion of the isolation structure that is located in the active area (i.e., the first isolation structure) is ensured. It should be noted that the connection lead L1 is not limited to being located in only one layer. The connection lead L1 may extend to the bonding area in one layer and be electrically connected to the bonding pad, or may be rerouted in multiple layers to extend to the bonding area and be electrically connect to the bonding pad.

In one embodiment, the first connection lead extends in the first direction. In one embodiment, two first connection leads are arranged in a second direction, the first direction intersecting the second direction. In one embodiment, the second isolation structure and the first isolation structure are disposed in the same layer. In one embodiment, the second isolation structure is electrically connected to the first isolation structure. In one embodiment, the second isolation structure is provided with no isolation opening. In one embodiment, an orthographic projection of the second isolation structure on the substrate covers at least part of an orthographic projection of the first isolation structure on the substrate. In one embodiment, the orthographic projection of the first isolation structure on the substrate covers at least part of the orthographic projection of the second isolation structure on the substrate; and in the first direction, the orthographic projection of the first isolation structure on the substrate is at least partially misaligned with the orthographic projection of the second isolation structure on the substrate.

In one embodiment, the second isolation structure is connected to the first connection lead by means of a via hole.

In one embodiment, in a thickness direction of the display panel, at least one insulating layer is provided between the first connection lead and the second isolation structure, and the via hole is formed in the insulating layer.

In one embodiment, the display panel further includes a third isolation structure located in the first bezel area; a dummy light-emitting element is provided in the third isolation opening formed by the third isolation structure; and the third isolation structure is located between the via hole and the active area. In one embodiment, the third isolation structure and the first isolation structure are disposed in the same layer. In one embodiment, the third isolation structure is electrically connected to the first isolation structure. In one embodiment, the third isolation structure and the first isolation structure are mesh connected.

It should be noted that the display panel in this embodiment may have the same configuration and effects as the display panel in the previous embodiment, and will not be described in detail here.

The present disclosure further provides a display device. As shown in FIG. 9, FIG. 9 is a structural schematic diagram of a display device according to an embodiment of the present disclosure. The display device includes a display panel according to any embodiment of the present disclosure, and the display device may be a cell phone, a tablet, an MP3, an MP4, a video phone, a personal digital assistant, a smart watch, a smart helmet or other wearable devices. The display device according to the embodiments of the present disclosure includes the display panel according to the embodiments of the present disclosure, and therefore also possesses the same beneficial effects, will not be described in detail here.

It should be understood that the steps may be reordered, added, or deleted using the various forms of processes illustrated above. For example, the steps recorded in the present disclosure may be performed in parallel, sequentially, or in a different order, provided that the desired results of the embodiments of the present disclosure can be achieved, which are not limited here.

The detailed description of the above embodiments does not constitute a limitation on the scope of protection of the present disclosure. It should be understood in the art that various modifications, combinations, sub-combinations, and substitutions can be made based on design requirements and other factors. Any modifications, equivalent substitutions, or improvements made within the spirit and principle of the present disclosure should be included within the scope of protection of the present disclosure.

1. A display panel, comprising:
an active area and a first bezel area arranged in a first direction, the first bezel area being provided with a bonding area;
a substrate;
a first isolation structure disposed in the active area and on one side of the substrate, the first isolation structure being provided with a plurality of first isolation openings, and light-emitting elements configured to be provided in the plurality of first isolation openings; and
a connection portion disposed in the first bezel area, one end of the connection portion being electrically connected to the first isolation structure.

2. The display panel according to claim 1, wherein the other end of the connection portion extends to the bonding area; and the connection portion comprises:
a second isolation structure disposed in the first bezel area and on one side of the substrate; and at least one first connection lead, a first end of the first connection lead overlapping and being connected to at least part of the second isolation structure, and a second end of the first connection lead extending to the bonding area,
wherein the first connection lead extends in the first direction;
the at least one first connection lead comprises two first connection leads arranged in a second direction, the first direction intersecting the second direction;
the second isolation structure and the first isolation structure are disposed in the same layer;
the second isolation structure is electrically connected to the first isolation structure; and
the second isolation structure is provided with no isolation opening.

3. The display panel according to claim 2, wherein the connection portion further comprises at least one second connection lead configured to extend in the second direction, each the second connection lead being electrically connected to at least two first connection leads;
the connection portion further comprises at least one third connection lead configured to extend in the first direction, a first end of the third connection lead overlapping and being connected to at least part of the second isolation structure, and a second end of the third connection lead being electrically connected to the second connection lead; and
the first connection lead, the second connection lead and the third connection lead are electrically connected to form a mesh structure.

4. The display panel according to claim 3, wherein the second connection lead is located between the bonding area and the active area, the third connection lead is located between two of the at least one first connection lead, and the first connection lead and the third connection lead are uniformly distributed in the second direction.

5. The display panel according to claim 3, wherein at least parts of at least two of the first connection lead, the second connection lead and the third connection lead are disposed in the same layer.

6. The display panel according to claim 5, wherein the substrate comprises a substrate base and a drive circuit layer disposed on the substrate base, the drive circuit layer comprising a predetermined metal layer close to the first isolation structure, and the first connection lead, the second connection lead, and the third connection lead each comprising a portion located in the predetermined metal layer, wherein the portion of the first connection lead that is located in the predetermined metal layer overlaps and is connected to the second isolation structure.

7. The display panel according to claim 2, wherein the second isolation structure is connected to the first connection lead by means of via holes;
each of the at least one first connection lead is connected to the second isolation structure by means of at least two of the via holes arranged in the first direction; and
in a thickness direction of the display panel, at least one insulating layer is provided between the first connection lead and the second isolation structure, and the via holes are formed in the insulating layer.

8. The display panel according to claim 7, wherein the connection portion further comprises a third isolation structure located in the first bezel area; the third isolation structure is provided with a third isolation opening, and a dummy light-emitting element is provided in the third isolation opening; and the third isolation structure is located between the via holes and the active area;
the third isolation structure and the first isolation structure are disposed in the same layer;
the third isolation structure is electrically connected to the first isolation structure;
the third isolation structure, the second isolation structure and the first isolation structure are integrated with one another; and
the third isolation structure and the first isolation structure are mesh connected.

9. The display panel according to claim 1, further comprising at least one second bezel area, wherein the second bezel area and the active area are arranged in a second direction, and the second bezel area and the first bezel area are located on opposite sides of the active area in the first direction, the second direction intersecting the first direction; and in a thickness direction of the display panel, an orthographic projection of the connection portion is located outside an orthographic projection of the second bezel area.

10. The display panel according to claim 9, further comprising a fourth isolation structure located in the second bezel area, wherein the fourth isolation structure is provided with a fourth isolation opening; a dummy light-emitting element is provided in the fourth isolation opening;
the fourth isolation structure and the first isolation structure are disposed in the same layer;
the fourth isolation structure is electrically connected to the first isolation structure; and
the fourth isolation structure and the first isolation structure are mesh connected.

11. The display panel according to claim 10, wherein the substrate comprises a substrate base and a drive circuit layer disposed on the substrate base, a portion of the drive circuit layer that is located in the second bezel area being formed with a plurality of dummy pixel drive circuits; each of the plurality of dummy pixel drive circuits corresponds to at least one dummy light-emitting element; and each of the plurality of dummy pixel drive circuits is insulated from the corresponding dummy light-emitting element.

12. The display panel according to claim 1, wherein the substrate comprises a substrate base and a drive circuit layer disposed on the substrate base, a portion of the drive circuit layer that is located in the active area being provided with a plurality of pixel drive circuits, each of the pixel drive circuits being connected to at least one of the light-emitting elements; and
a portion of the drive circuit layer that is located in the first bezel area is provided with a plurality of power signal leads, each of the power signal leads having one end electrically connected to the active area and the other end extending to the bonding area.

13. The display panel according to claim 1, wherein the first isolation structure comprises a support portion and a crown; and in a thickness direction of the display panel, an orthographic projection of the support portion on the substrate is located within an orthographic projection of the crown on the substrate, wherein the support portion is an electrically conductive structure.

14. The display panel according to claim 13, further comprising at least one dam configured to surround the active area, the dam being provided with a dam opening.

15. The display panel according to claim 13, further comprising a plurality of first electrodes disposed in the plurality of isolation openings and located on a side of the light-emitting elements away from the substrate, wherein the first electrodes overlap and are connected to the support portion.

16. A display panel, comprising:
an active area and a first bezel area arranged in a first direction, the first bezel area being provided with a bonding area;
a substrate;
a first isolation structure disposed in the active area and on one side of the substrate, the first isolation structure being provided with a plurality of first isolation openings, and light-emitting elements configured to be provided in the plurality of first isolation openings; and
a connection portion configured to have one end electrically connected to the first isolation structure, wherein the connection portion is located only in the first bezel area.

17. The display panel according to claim 16, wherein the other end of the connection portion extends to the bonding area; and the connection portion comprises:
a second isolation structure disposed in the first bezel area and on one side of the substrate; and
at least one first connection lead, a first end of the first connection lead overlapping and being connected to at least part of the second isolation structure, and a second end of the first connection lead extending to the bonding area,
wherein the first connection lead extends in the first direction;
the at least one first connection lead comprises two first connection leads arranged in a second direction, the first direction intersecting the second direction;
the second isolation structure and the first isolation structure are disposed in the same layer;
the second isolation structure is electrically connected to the first isolation structure; and
the second isolation structure is provided with no isolation opening.

18. The display panel according to claim 17, wherein the second isolation structure is connected to the first connection lead by means of a via hole;
in a thickness direction of the display panel, at least one insulating layer is provided between the first connection lead and the second isolation structure, and the via hole is formed in the insulating layer;
the connection portion further comprises a third isolation structure located in the first bezel area; the third isolation structure is provided with a third isolation opening, and a dummy light-emitting element provided in the third isolation opening; and the third isolation structure is located between the via hole and the active area;
the third isolation structure and the first isolation structure are disposed in the same layer;
the third isolation structure is electrically connected to the first isolation structure;
the third isolation structure, the second isolation structure and the first isolation structure are integrated with one another; and
the third isolation structure and the first isolation structure are mesh connected.

19. The display panel according to claim 16, further comprising at least one second bezel area, wherein the second bezel area and the active area are arranged in a second direction, and the second bezel area and the first bezel area are located on opposite sides of the active area in the first direction, the second direction intersecting the first direction; and
in a thickness direction of the display panel, an orthographic projection of the connection portion is located outside an orthographic projection of the second bezel area.

20. A display device, comprising:
a display panel, comprising:
an active area and a first bezel area arranged in a first direction, the first bezel area being provided with a bonding area;
a substrate;
a first isolation structure disposed in the active area and on one side of the substrate, the first isolation structure being provided with a plurality of first isolation openings, and light-emitting elements configured to be provided in the plurality of first isolation openings; and
a connection portion disposed in the first bezel area, one end of the connection portion being electrically connected to the first isolation structure.
